(19) United States
(12) Patent Application Publication
(10) Pub. No.: US 2025/0163222 A1
(43) Pub. Date: May 22, 2025

(54) MODIFIED BISMALEIMIDE PREPOLYMER, RESIN COMPOSITION AND USE OF RESIN COMPOSITION

(71) Applicants: SHENGYI TECHNOLOGY (SUZHOU) CO., LTD, Suzhou, Jiangsu (CN); SHENGYI TECHNOLOGY (CHANGSHU) CO., LTD, Suzhou, Jiangsu (CN)

(72) Inventors: Xiangxiu CHEN, Suzhou (CN); Feng JIAO, Suzhou (CN); Hui WANG, Suzhou (CN); Chunmei CUI, Suzhou (CN); Jian MA, Suzhou (CN)

(73) Assignees: SHENGYI TECHNOLOGY (SUZHOU) CO., LTD, Suzhou, Jiangsu (CN); SHENGYI TECHNOLOGY (CHANGSHU) CO., LTD, Suzhou, Jiangsu (CN)

(21) Appl. No.: 18/837,134

(22) PCT Filed: Mar. 31, 2023
(86) PCT No.: PCT/CN2023/085348

§ 371 Date: Aug. 8, 2024

(30) Foreign Application Priority Data
Oct. 11, 2022 (CN) 202211241813.0
Oct. 11, 2022 (CN) 202211241831.9
Oct. 11, 2022 (CN) 202211244008.3

(51) Int. Cl. C08G 77/455; B32B 15/08; B32B 15/20; C08K 5/5399; C08K 5/5435; H05K 1/03

(52) U.S. Cl. CPC C08G 77/455; B32B 15/08; B32B 15/20; C08K 5/5399; C08K 5/5435; B32B 2457/08; H05K 1/0373

(57) ABSTRACT

The invention provides a modified bismaleimide prepolymer, prepared by a reaction of a bismaleimide compound, a double bond-containing organic silicone resin and a hydrocarbon resin. A mass ratio of the bismaleimide compound to the double bond-containing organic silicone resin to the hydrocarbon resin is 100:(3-40):(5-50). According to the invention, a silicon-oxygen bond and a carbon-hydrogen bond are introduced into the bismaleimide compound, and the mass ratio of the bismaleimide compound to the double bond-containing organic silicone resin to the hydrocarbon resin is controlled, thereby improving the polymerization processability and the toughness and dielectric properties of the bismaleimide compound curing system.

The present application claims the priority to the Chinese Patent Application having an application date of Oct. 11, 2022, an application number of 202211244008.3, and a title of “MODIFIED BISMALEIMIDE PREPOLYMER, RESIN COMPOSITION AND APPLICATION OF RESIN COMPOSITION”, which is incorporated herein by reference in its entirety.

### TECHNICAL FIELD

The invention relates to the technical field of electronic materials, and in particular, to a modified bismaleimide prepolymer, a resin composition and use of the resin composition.

### BACKGROUND

With the upgrade of technology, consumer electronics markets of automobiles, smart phones and the like put forward new requirements for PCB. Since 5G came into commercial use in 2018, requirements for dielectric properties of PCB substrates have reached a higher level. A high-frequency and high-speed copper clad laminate is one of indispensable electronic substrates in the 5G era, which makes a PCB substrate material need to have lower dielectric constant and dielectric loss tangent, so as to reduce the delay, distortion and loss of signals as well as the interference between the signals during high-speed transmission. Therefore, it is desirable to provide a thermosetting resin composition. A printed circuit board material made of such thermosetting resin composition may exhibit sufficiently low dielectric constant and low dielectric loss tangent in the process of high-speed and high-frequency signal transmission (that is, it is preferred that the dielectric constant and dielectric loss tangent are as low as possible), and meanwhile, it requires high heat resistance, high modulus, low CTE, etc.

A bismaleimide resin cured product has excellent properties such as high temperature resistance, damp heat resistance, high modulus, low CTE, high strength, etc. It is suitable to be used as a matrix resin for IC package substrates and substrate-like PCBs, but its application in the field of high-frequency and high-speed package substrates is limited by the problem of poor dielectric properties.

In order to improve the poor dielectric properties of a bismaleimide resin, a polyphenylene oxide resin is introduced into the bismaleimide resin in the prior art, thereby reducing the dielectric properties of the bismaleimide resin cured product to some extent. However, the polyphenylene oxide resin has the characteristics of a thermoplastic resin, and its compatibility with the bismaleimide resin is poor, so it is difficult to obtain a well homogenized colloid-liquid complex. In the prior art, a reactive organic silicone resin is also introduced into a bismaleimide resin system to improve heat resistance and reduce CTE value, but there is still room for improvement in dielectric properties.

### SUMMARY

An objective of the invention is to provide a modified bismaleimide prepolymer, a resin composition and use of the resin composition. A silicon-oxygen bond and a carbon-hydrogen bond are introduced into the bismaleimide compound, and a weight ratio of the bismaleimide compound to the double bond-containing organic silicone resin to the hydrocarbon resin is controlled, thereby improving the polymerization processability and the toughness and dielectric properties of the bismaleimide curing system, and solving the problems of high brittleness and poor dielectric properties of the bismaleimide curing system in the prior art.

To achieve one of the above objects, an implementation of the invention provides a modified bismaleimide prepolymer, which is prepared by a reaction of a bismaleimide compound, a double bond-containing organic silicone resin and a hydrocarbon resin, where a mass ratio of the bismaleimide compound to the double bond-containing organic silicone resin to the hydrocarbon resin is 100:(3-40):(5-50).

As a further improvement of an implementation of the invention, a ratio of a sum of double bond equivalents of the double bond-containing organic silicone resin and the hydrocarbon resin to a double bond equivalent of the bismaleimide compound is 1:(5-0.8).

As a further improvement of an implementation of the invention, the modified bismaleimide prepolymer is prepared by the following reactions:
reacting the bismaleimide compound with the double bond-containing organic silicone resin at 50-90° C. for 30-120 min to obtain a pre-reactant; and
adding the hydrocarbon resin to the pre-reactant, and carrying out a reaction at 90-130° C. for 30-150 min to obtain the modified bismaleimide prepolymer.

As a further improvement of an implementation of the invention, 0.1-10 parts by weight of at least one of aminophenol, carboxylic acid or carboxylic anhydride is added during the reaction process of the bismaleimide compound, the double bond-containing organic silicone resin and the hydrocarbon resin.

As a further improvement of an implementation of the invention, the obtained modified bismaleimide prepolymer contains reactive double bonds.

To achieve one of the above objects, an implementation of the invention also provides a resin composition which comprises the following ingredients in parts by weight:
(a) modified bismaleimide prepolymer: 10-80 parts; and
(b) maleimide compound or derivatives thereof: 10-80 parts;
where the modified bismaleimide prepolymer is the foregoing modified bismaleimide prepolymer.

As a further improvement of an implementation of the invention, the resin composition further comprises 3-50 parts by weight of elastomer, the elastomer being at least one of a styrene elastomer, a methacrylate elastomer and an organic silicone elastomer.

As a further improvement of an implementation of the invention, the resin composition further comprises 5-50 parts by weight of flame retardant.

As a further improvement of an implementation of the invention, the flame retardant is selected from a bromine flame retardant, a phosphorus flame retardant, a nitrogen flame retardant, an organic silicone flame retardant and an organic metal salt flame retardant;
the bromine flame retardant is selected from decabromodiphenyl ether, decabromodiphenyl ethane, brominated styrene or tetrabromophthalamide;
the phosphorus flame retardant is selected from inorganic phosphorus, phosphate ester, phosphoric acid, hypophosphorous acid, phosphorus oxide, 9,10-dihydro-9-oxa-10-phosphaphenanthrene-10-oxide (DOPO), 10-(2,5-dihydroxyphenyl)-9,10-dihydro-9-oxa-10-phosphaphenanthrene-10-oxide (DOPO-HQ),

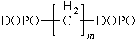

(m is an integer of 1 to 5),

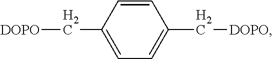

10-phenyl-9,10-dihydro-9-oxa-10-phosphaphenanthrene-10-oxide, tris(2,6-dimethylphenyl)phosphine, phosphazene and modified phosphazene;
the nitrogen flame retardant is selected from a triazine compound, a cyanuric acid compound, an isocyanic acid compound and phenothiazine;
the organic silicone flame retardant is selected from organic silicone oil, organic silicone rubber and organic silicone resin; and
the organic metal flame retardant is selected from ferrocene, an acetylacetone metal complex and an organic metal carbonyl compound.

As a further improvement of an implementation of the invention, the resin composition further comprises a silane coupling agent and a dispersant, a weight ratio of the silane coupling agent to the dispersant being (2-10): 1.

As a further improvement of an implementation of the invention, the silane coupling agent is an epoxy silane coupling agent, and the dispersant is a phosphate ester dispersant and/or a modified polyurethane dispersant.

An implementation of the invention also provides use of the foregoing resin composition in a semi-cured sheet, a laminate, an insulating film, an insulating board, a copper clad laminate, a circuit substrate and an electronic device.

One or more technical solutions provided in the in
vention at least has the following technical effects or advantages:

(1) According to the invention, by carrying out on the bismaleimide compound, the double bond-containing organic silicone resin and the hydrocarbon resin, the silicon-oxygen bond and the carbon-hydrogen bond are introduced into the bismaleimide compound, thereby improving the polymerization processability and the toughness and dielectric properties of the bismaleimide compound curing system.

(2) According to the invention, the weight ratio of the bismaleimide compound to the double bond-containing organic silicone resin to the hydrocarbon resin is controlled to control the modification degree of the bismaleimide compound, so that the dielectric properties and brittleness are improved while the high heat resistance and low CTE are maintained, and the modified bismaleimide prepolymer can be well applied to high-frequency and high-speed package substrates.

### DETAILED DESCRIPTION

The invention will be described in detail below in conjunction with specific embodiments, but the invention is not limited by these embodiments. Changes in reaction conditions, reactants or amounts of raw materials made by those of ordinary skill in the art according to these embodiments are included in the protection scope of the invention.

An example of the invention provides a modified bismaleimide prepolymer, prepared by a reaction of a bismaleimide compound, a double bond-containing organic silicone resin and a hydrocarbon resin. A mass ratio of the bismaleimide compound to the double bond-containing organic silicone resin to the hydrocarbon resin is 100:(3-40):(5-50).

Further, a ratio of a sum of double bond equivalents of the double bond-containing organic silicone resin and the hydrocarbon resin to a double bond equivalent of the bismaleimide compound is 1:(5-0.8).

The modified bismaleimide prepolymer is prepared by the following reactions:
reacting the bismaleimide compound with the double bond-containing organic silicone resin at 50-90° C. for 30-120 min to obtain a pre-reactant; and
adding the hydrocarbon resin to the pre-reactant, and carrying out a reaction at 90-130° C. for 30-150 min to obtain the modified bismaleimide prepolymer.
0.1-10 parts by weight of at least one of aminophenol, carboxylic acid or carboxylic anhydride is added during the reaction process of the bismaleimide compound, the double bond-containing organic silicone resin and the hydrocarbon resin. The phenolic hydroxyl, carboxyl and anhydride groups in the aminophenol, carboxylic acid or carboxylic acid can all react with the bismaleimide compound to improve the reactivity.

Further, the modified bismaleimide prepolymer obtained in the foregoing reaction contains reactive double bonds, which can improve the reactivity of the modified bismaleimide prepolymer during curing.

The double bond in the bismaleimide compound reacts with the double bond in the double bond-containing organic silicone resin, so that the silicon-oxygen bond is introduced into the bismaleimide compound. The silicon-oxygen bond can improve the toughness of the bismaleimide compound. Then, by using the hydrocarbon resin, the crosslinking density of the cured product is improved, the overall free radical reaction speed is controlled, and the unreacted carbon-carbon double bond is effectively retained, thereby improving the reactivity of the modified bismaleimide prepolymer.

Further, during the preparation process of the modified bismaleimide prepolymer, a right amount of initiator may be added. Based on 100 parts by weight of the resin composition, the amount of the initiator is 0.001-6 parts by weight. The initiator may be selected from an azo initiator, a peroxide initiator and a redox initiator, preferably one or more of the following initiators: dicumyl peroxide, di-tert-butyl peroxide, tert-butyl peroxybenzoate, dicyclohexyl peroxydicarbonate, cumene hydroperoxide and azobisisobutyronitrile.

Further, the double bond-containing organic silicone resin is shown as the following structural formula (1):

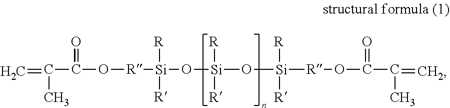

where R and R′ are C1-C5 alkyl or at least one of them is a reactive group, R″ is C1-C5 alkylene, and n is an integer of 1 to 30.

Preferably, the side chains R and R′ of the double bond-containing organic silicone resin contain at least one carbon-carbon double bond, and the group containing the carbon-carbon double bond is vinyl, allyl, propenyl, styryl or methacrylate group. The reactive groups on the side chains of the double bond-containing organic silicone resin improve the reactivity of the bismaleimide prepolymer during the polymerization process.

Further, the hydrocarbon resin contains 1,2-vinyl, and a content of the 1,2-vinyl is ≥70%. Preferably, the content of the 1,2-vinyl in the hydrocarbon resin is 80-98%.

An example of the invention further provides a resin composition, including the following ingredients in parts by weight:
(a) modified bismaleimide prepolymer: 10-80 parts; and
(b) maleimide resin or derivatives thereof: 10-80 parts.

The modified bismaleimide prepolymer is the foregoing modified bismaleimide prepolymer.

Further, the bismaleimide compound in the maleimide resin or the modified bismaleimide prepolymer is selected from at least one of the following structures:

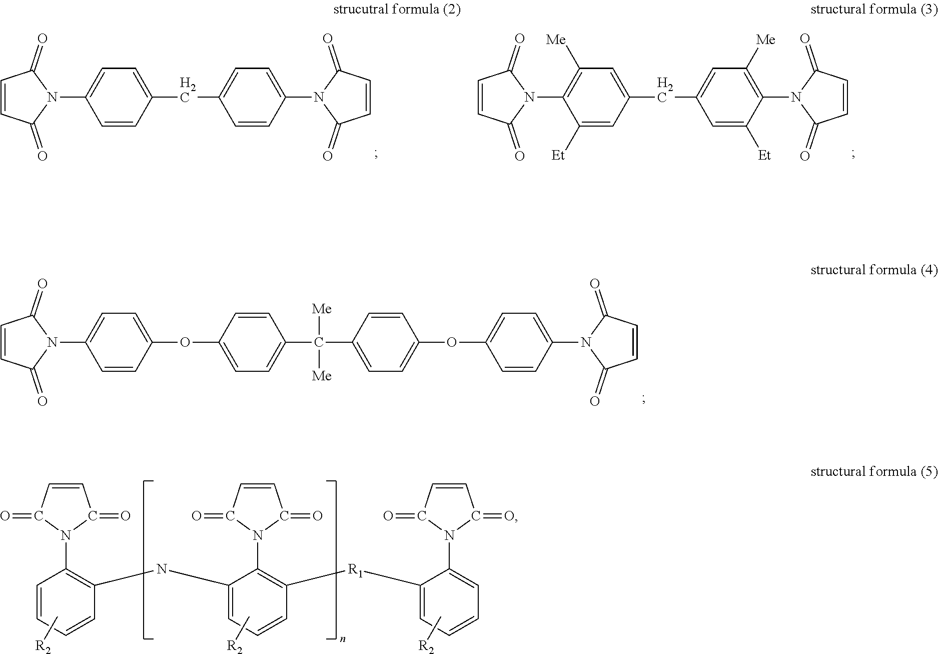

where R2 is hydrogen, methyl or ethyl, R1 is methylene, ethylene or

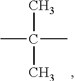

and n is an integer of 1 to 10;

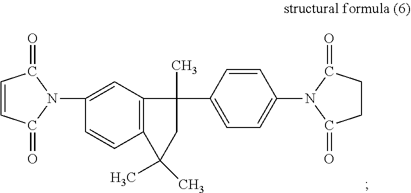

where n is an integer of 1 to 10;

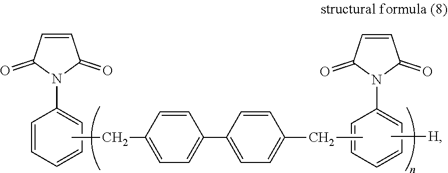

where n is an integer of 1 to 10;

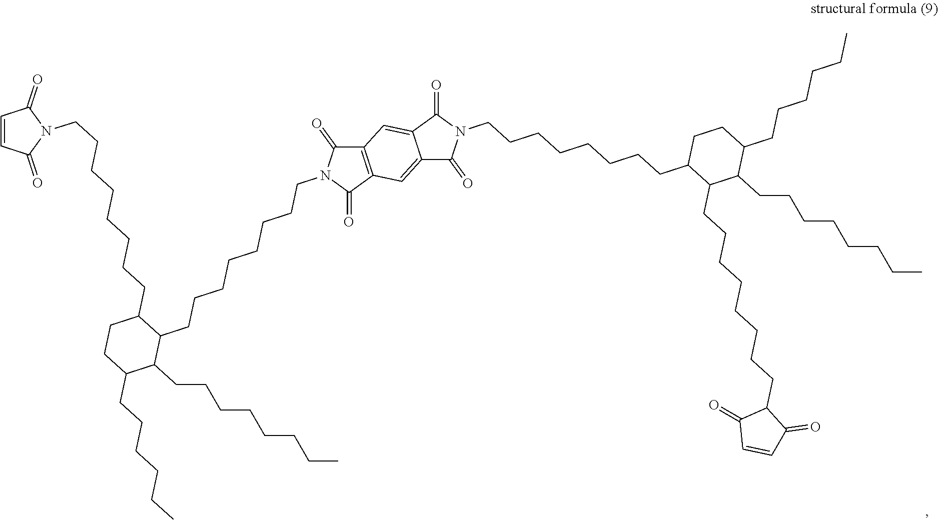

where n is an integer of 1 to 10;

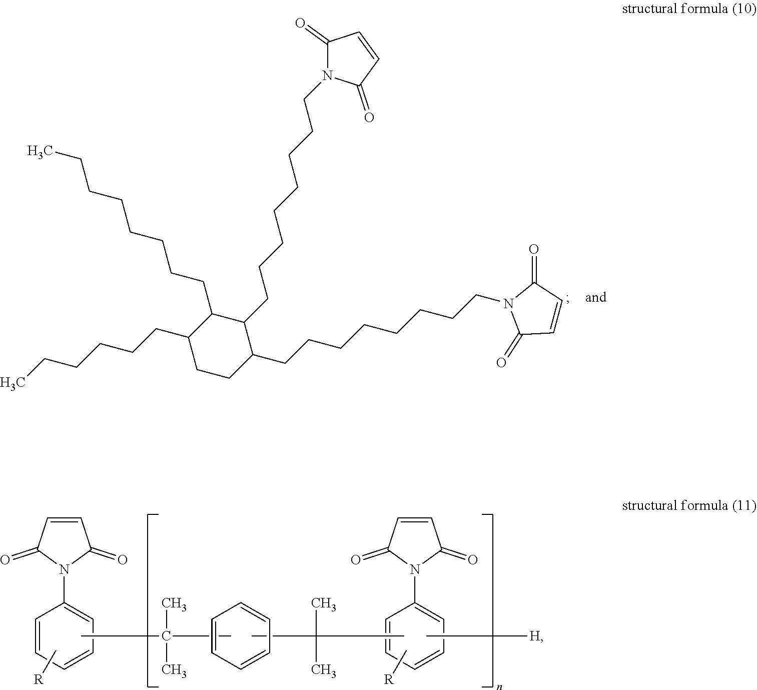

where R is hydrogen, methyl or ethyl, and n is an integer of 1 to 10.

Further, the resin composition further includes 0.001-5 parts by weight of catalyst, selected from 2-methylimidazole, 2-ethyl-4-methylimidazole, 2-phenylimidazole, 2-undecylimidazole, 1-benzyl-2-methylimidazole, 2-heptadecylimidazole, 2-isopropylimidazole, 2-phenyl-4-methylimidazole, 2-dodecylimidazole, 1-cyanoethyl-2-methylimidazole or at least one of modified imidazoles shown as the following structures:

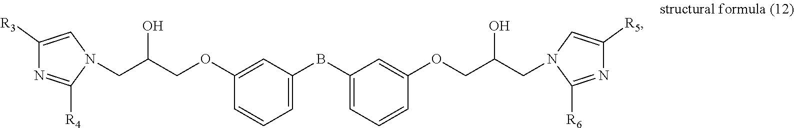

which may be P200F50 by JER, where R3, R4, R5 and R6 are the same or different and are respectively methyl, ethyl or tert-butyl, and B is methylene, ethylene,

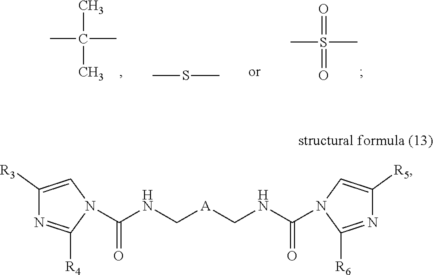

which may be G8009L by DKS, where R3, R4, R5 and R6 are the same or different and are respectively methyl, ethyl or tert-butyl, and A is methylene, ethylene,

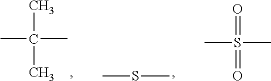

or aromatic hydrocarbon group.

Further, the resin composition further includes 3-50 parts by weight of elastomer. The elastomer is at least one of a styrene elastomer, a methacrylate elastomer and an organic silicone elastomer.

The styrene elastomer is selected from H1041, H1043, H1051, H1052, H1053, H1221, P1500, P2000, M1911 or M1913 by Asahi Kasei, Japan; or 8004, 8006, 8076, 8104, V9827, 2002, 2005, 2006, 2007, 2104, 7125, 4033, 4044, 4055, 4077 or 4099 by Kuraray.

The methacrylate elastomer is selected from M51, M52, M22 or D51N by Arkema; or LA-2330 by Kuraray; or SG-P3 series or SG-80 series by Nagase.

The organic silicone elastomer is selected from X-40-2670, R-170S, X-40-2705, X-40-2701, KMP-600, KMP-605 or X-52-7030 by Shin-Etsu Chemical; or AY-42-119, EP-2600, EP-2601, EP-2720, TMS-2670, EXL-2315 or EXL-2655 by DOW.

Further, the resin composition further includes a silane coupling agent and a dispersant. The silane coupling agent is an epoxy silane coupling agent, and a weight ratio of the silane coupling agent to the dispersant is (2-10): 1. The dispersant is a phosphate ester dispersant and/or a modified polyurethane dispersant.

Further, the resin composition further includes 5-50 parts by weight of flame retardant. The flame retardant is selected from a bromine flame retardant, a phosphorus flame retardant, a nitrogen flame retardant, an organic silicone flame retardant, an organic metal salt flame retardant, etc.

Specifically, the bromine flame retardant is selected from decabromodiphenyl ether, decabromodiphenyl ethane, brominated styrene or tetrabromophthalamide.

The phosphorus flame retardant is selected from inorganic phosphorus, phosphate ester, phosphoric acid, hypophosphorous acid, phosphorus oxide, 9,10-dihydro-9-oxa-10-phosphaphenanthrene-10-oxide (DOPO), 10-(2,5-dihydroxyphenyl)-9,10-dihydro-9-oxa-10-phosphaphenanthrene-10-oxide (DOPO-HQ),

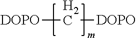

(m is an integer of 1 to 5),

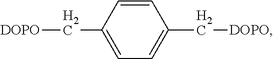

10-phenyl-9,10-dihydro-9-oxa-10-phosphaphenanthrene-10-oxide, tris(2,6-dimethylphenyl)phosphine, phosphazene, modified phosphazene and other organic phosphorus-containing compounds.

The nitrogen flame retardant is selected from a triazine compound, a cyanuric acid compound, an isocyanic acid compound, phenothiazine, etc.

The organic silicone flame retardant is selected from organic silicone oil, organic silicone rubber, organic silicone resin, etc.

The organic metal flame retardant is selected from ferrocene, an acetylacetone metal complex, an organic metal carbonyl compound, etc.

The flame retardant is selected from phosphazene with grade SPB-100 by Otsuka Chemical, and modified phosphazene with grades BP-PZ, PP-PZ, SPCN-100, SPV-100 and SPB-100L.

Further, the resin composition further includes a filler. Based on 100 parts by weight of the resin composition, a content of the filler is 20-80 parts by weight. The filler includes an inorganic filler, an organic filler and a composite filler. The inorganic filler is selected from at least one of fused silica, crystalline silica, spherical silica, hollow silica, aluminum hydroxide, alumina, talcum powder, aluminum nitride, boron nitride, silicon carbide, barium sulfate, barium titanate, strontium titanate, calcium carbonate, calcium silicate, mica and glass fiber powder. The organic filler is selected from at least one of polytetrafluoroethylene powder, polyphenylene sulfide powder and polyethersulfone powder.

The filler is surface-treated with a silane coupling agent. The silane coupling agent is selected from KBM-573 by Shin-Etsu Chemical, Z-6883 by DOW, KBM-1003 by Shin-Etsu Chemical and KBM-1403 by Shin-Etsu Chemical.

Further, dyes, such as fluorescent dyes or black dyes, may also be added to the resin composition.

The invention further provides use of the resin composition in a semi-cured sheet a laminate, an insulating film, an insulating board, a circuit substrate and an electronic device. The specific description is as follows:

The invention further provides a semi-cured sheet, including a reinforcing material and the foregoing resin composition. A method for preparing the semi-cured sheet includes: dissolving the resin composition in a solvent to obtain a colloid liquid, impregnating the reinforcing material in the colloid liquid, taking out the impregnated reinforcing material, and baking the reinforcing material at 100-180° C. for 1-15 min; and carrying out drying to obtain the semi-cured sheet.

The solvent is selected from at least one of acetone, butanone, toluene, methyl isobutyl ketone, N,N-dimethylformamide, N,N-dimethylacetamide, ethylene glycol methyl ether, propylene glycol methyl ether, benzene, toluene, xylene and cyclohexane.

The reinforcing material is selected from at least one of natural fiber, organic synthetic fiber, organic fabric and inorganic fabric. Preferably, the reinforcing material is glass fiber cloth. The glass fiber cloth is preferably filament spread cloth or flattened cloth. The glass fiber cloth is preferably E-glass fiber cloth, S-glass fiber cloth or Q-glass fiber cloth.

In addition, when the reinforcing material is glass fiber cloth, the glass fiber cloth is chemically treated with a coupling agent to improve interface bonding between the resin composition and the glass fiber cloth. The coupling agent is preferably an epoxy silane coupling agent or an amino silane coupling agent so as to provide good water resistance and heat resistance.

An example of the invention further provides a laminate, including a semi-cured sheet mentioned above and metal foil arranged on a surface on at least one side of the semi-cured sheet; or including a composite sheet formed by laminating a plurality of the foregoing semi-cured sheets, and metal foil arranged on a surface on at least one side of the composite sheet.

A method for preparing the laminate includes: applying the metal foil to the surface on one or both sides of one semi-cured sheet, or laminating at least two semi-cured sheets to form the composite sheet and applying the metal foil to the surface on one or both sides of the composite sheet, and carrying out hot pressing to obtain the metal foil laminate. The hot pressing is carried out under a pressure of 0.2-2 MPa at 150-250° C. for 2-4 h.

Preferably, the metal foil is selected from copper foil or aluminum foil. The metal foil has a thickness of 5 μm, 8 μm, 12 μm, 18 μm, 35 μm or 70 μm.

An example of the invention further provides an insulating board, including at least one semi-cured sheet mentioned above.

An example of the invention further provides an insulating film, including a carrier film and the foregoing resin composition applied thereto. The heat index of the insulating film is obviously improved.

A method for preparing the insulating film includes: dissolving the foregoing resin composition in a solvent to obtain a colloid liquid, applying the colloid liquid to the carrier film, and heat-drying the carrier film with the colloid liquid to obtain the insulating film.

The foregoing solvent is selected from at least one of acetone, butanone, toluene, methyl isobutyl ketone, N,N-dimethylformamide, N,N-dimethylacetamide, ethylene glycol methyl ether, propylene glycol methyl ether, benzene, toluene, xylene and cyclohexane.

The carrier film is selected from at least one of a PET film, a PP film, a PE film and a PVC film.

An example of the invention further provides a circuit substrate, including one or more of the semi-cured sheet, the laminate, the insulating board and the insulating film mentioned above.

An example of the invention further provides an electronic device, including the circuit substrate mentioned above. Since the heat resistance of the circuit substrate is greatly improved, the safety of the electronic device is significantly improved.

The technical solutions of this application will be further described below in conjunction with some specific synthesis examples and comparative examples.

### Synthesis Example 1: Modified Bismaleimide Prepolymer Y1

Step 1:200 g of bismaleimide resin (BMI-2300 by Daiwa Kasei), 20 g of double bond-containing organic silicone resin (X-22-164A by Shin-Etsu Chemical) and a right amount of organic solvent were added to a beaker and reacted at 80° C. for 70 min to obtain a pre-reactant.

Step 2: The temperature was raised to 110° C., and 30 g of hydrocarbon resin (B3000 by Nippon Soda) was added. The reaction was continued at 110° C. for 30 min to obtain the modified bismaleimide prepolymer Y1.

### Synthesis Example 2: Modified Bismaleimide Prepolymer Y2

Step 1:200 g of bismaleimide resin (MIR-3000 by Nippon Kayaku), 30 g of double bond-containing organic silicone resin (X-22-164A by Shin-Etsu Chemical) and a right amount of organic solvent were added to a beaker and reacted at 90° C. for 60 min to obtain a pre-reactant.

Step 2: The temperature was raised to 120° C., and 45 g of hydrocarbon resin (B2000 by Nippon Soda) was added. The reaction was continued at 120° C. for 30 min to obtain the modified bismaleimide prepolymer Y2.

### Synthesis Example 3: Modified Bismaleimide Prepolymer Y3

Step 1:200 g of bismaleimide resin (MIR-3000 by Nippon Kayaku) and 40 g of double bond-containing organic silicone resin (X-22-164A) were added to a beaker and reacted at 90° C. for 60 min to obtain a pre-reactant.

Step 2: The temperature was raised to 120° C., and 25 g of hydrocarbon resin (B3000 by Nippon Soda) was added. The reaction was continued at 120° C. for 30 min to obtain the modified bismaleimide prepolymer Y3.

### Synthesis Example 4: Modified Bismaleimide Prepolymer Y4

200 g of bismaleimide resin (BMI-2300 by Daiwa Kasei), 20 g of double bond-containing organic silicone resin (X-22-164A by Shin-Etsu Chemical), 30 g of hydrocarbon resin (B3000 by Nippon Soda) and a right amount of organic solvent were added to a beaker and reacted at 100° C. for 100 min to obtain the modified bismaleimide prepolymer Y4.

### Synthesis Example 5: Modified Bismaleimide Prepolymer Y5 (Compared with Synthesis Example 1)

Step 1:200 g of bismaleimide resin (BMI-2300 by Daiwa Kasei), 30 g of hydrocarbon resin (B3000 by Nippon Soda) and a right amount of organic solvent were added to a beaker and reacted at 80° C. for 70 min to obtain a pre-reactant.

Step 2: The temperature was raised to 110° C., and 20 g of double bond-containing organic silicone resin (X-22-164A by Shin-Etsu Chemical) was added. The reaction was continued at 110° C. for 30 min to obtain the modified bismaleimide prepolymer Y5.

### Synthesis Comparative Example 1: Modified Bismaleimide Prepolymer Y6

200 g of bismaleimide resin (BMI-2300 by Daiwa Kasei), 20 g of double bond-containing organic silicone resin (X-22-164A by Shin-Etsu Chemical) and a right amount of organic solvent were added to a beaker and reacted at 110° C. for 120 min to obtain a pre-reactant Y4.

### Synthesis Comparative Example 2: Modified Bismaleimide Prepolymer Y7

200 g of bismaleimide resin (BMI-2300 by Daiwa Kasei), 45 g of hydrocarbon resin (B3000 by Nippon Soda) and 0.1 g of initiator were added to a beaker and reacted at 110° C. for 120 min to obtain a pre-reactant Y5.

The corresponding solid materials were weighed according to the data in Table 1. The solvent was added to the solid materials such that a solid content of the colloid liquid was adjusted to 60%. The colloid liquid was applied to E-glass fiber cloth. The impregnated E-glass fiber cloth was taken out, put into an air blast dryer at 160° C., and baked for 3-6 min to obtain the semi-cured sheet.

The semi-cured sheet was cut to a size of 300 mm×300 mm. Electrolytic copper foil was placed and stacked to both sides of the semi-cured sheet to obtain a stacked structure. The stacked structure was sent into a vacuum press and pressed into a metal foil laminate (or copper clad laminate). The specific performance testing is shown in Table 2.

TABLE 1
Formula of resin composition

| | Example | Example | Example | Example | Example | Comparative | Comparative |
|---|---|---|---|---|---|---|---|
| Ingredient | 1 | 2 | 3 | 4 | 5 | Example 1 | Example 2 |
| Prepolymer | 30 | — | 20 | — | — | — | — |
| Y1 | | | | | | | |
| Prepolymer | — | 50 | 10 | — | — | — | — |
| Y2 | | | | | | | |
| Prepolymer | — | — | 10 | | — | — | — |
| Y3 | | | | | | | |
| Prepolymer | — | — | — | 30 | — | — | — |
| Y4 | | | | | | | |
| Prepolymer | — | — | — | — | 30 | — | — |
| Y5 | | | | | | | |
| Prepolymer | — | — | — | — | — | 50 | — |
| Y6 | | | | | | | |
| Prepolymer | — | — | — | — | — | — | 30 |
| Y7 | | | | | | | |
| Maleimide | 45 | — | 35 | 45 | 45 | — | 45 |
| (structural | | | | | | | |
| formula 4) | | | | | | | |
| Maleimide | — | 25 | — | — | — | 25 | — |
| (structural | | | | | | | |
| formula 9) | | | | | | | |
| Imidazole | 0.1 | 0.1 | 0.1 | 0.1 | 0.1 | 0.1 | 0.1 |
| G8009L | | | | | | | |
| Elastomer | 10 | 10 | 10 | 10 | 10 | 10 | 10 |
| Styrene- | | | | | | | |
| butadiene | | | | | | | |
| Modified | 15 | 15 | 15 | 15 | 15 | 15 | 15 |
| phosphazene | | | | | | | |
| (SPV-100) | | | | | | | |
| Silica filler | 122 | 122 | 122 | 122 | 122 | 122 | 122 |

TABLE 2
Performance table

| | Example | Example | Example | Example | Example | Comparative | Comparative |
|---|---|---|---|---|---|---|---|
| Performance | 1 | 2 | 3 | 4 | 5 | Example 1 | Example 2 |
| Tg/° C. | 302 | 290 | 305 | 297 | 289 | 260 | 266 |
| Dk (10 GHz) | 2.88 | 2.82 | 2.85 | 2.90 | 2.79 | 3.10 | 2.96 |
| Df (10 GHz) | 0.0035 | 0.0026 | 0.0030 | 0.0039 | 0.0033 | 0.0035 | 0.0037 |
| CTE (X − Y, | 6 | 7 | 7 | 8 | 7 | 8 | 9 |
| α1)/° C. − 1 | | | | | | | |
| Water | 0.32 | 0.31 | 0.30 | 0.38 | 0.39 | 0.30 | 0.40 |
| absorption/% | | | | | | | |
| Sub-surface | OK | OK | OK | OK | OK | White lines | White lines |
| defect of | | | | | | scattered in | scattered in |
| laminate | | | | | | the laminate | the laminate |

Semi-cured sheets and copper clad laminates prepared in all of the above Examples 1 to 5 and Comparative Examples 1 to 3 were subjected to performance testing.

1) The glass transition temperature was determined by DMA (dynamic mechanical analysis) at a heating rate of 10° C./min.

2) Determination of PCT 2 HR water absorption: 3 samples were taken, each of which was 10 cm×10 cm in size and 0.40 mm in thickness with metal foils removed from both sides. Each sample was dried at 100° C. for 2 h before being weighed, and the weight was recorded as W1. Then, each sample was treated in a pressure cooker test machine at 121° C. and 2 atm for 2 h before being weighed, and the weight was recorded as W2. The water absorption was determined as (W2−W1)/W1×100%.

3) Determination of X/Y coefficient of thermal expansion (CTE): TMA (thermomechanical analysis) was used at a heating rate of 10° C./min at a test temperature ranging from 30 to 100° C.

4) Dk and Df: Determination was carried out according to IPC-TM-650 2.5.5.9, using a plate method at 10 GHz.

From the foregoing experimental data, Examples 1 to 5 have excellent high Tg, low dielectric constant and dielectric loss, low water absorption and low CTE value. Among them, Example 2 has higher Tg value, and lower dielectric constant and dielectric loss than Comparative Example 1; and Example 1 has higher Tg value, lower dielectric constant and dielectric loss, and lower CTE and water absorption than Comparative Example 2.

It should be understood that although this specification is described according to the embodiments, not every embodiment only contains an independent technical solution. This description of the specification is merely for the sake of clarity. Those skilled in the art should take the specification as a whole, and the technical solutions in various embodiments may also be combined appropriately to form other embodiments which may be understood by those skilled in the art.

The series of detailed descriptions listed above are only specific descriptions for feasible embodiments of the invention, and they are not used to limit the protection scope of the invention. Any equivalent embodiments or alterations which do not depart from the technical spirit of the invention should be included in the protection scope of the invention.

What is claimed is:

1. A modified bismaleimide prepolymer, prepared by a reaction of a bismaleimide compound, a double bond-containing organic silicone resin and a hydrocarbon resin, wherein a mass ratio of the bismaleimide compound to the double bond-containing organic silicone resin to the hydrocarbon resin is 100:(3-40):(5-50).

2. The modified bismaleimide prepolymer according to claim 1, wherein a ratio of a sum of double bond equivalents of the double bond-containing organic silicone resin and the hydrocarbon resin to a double bond equivalent of the bismaleimide compound is 1:(5-0.8).

3. The modified bismaleimide prepolymer according to claim 1, prepared by the following reactions:
reacting the bismaleimide compound with the double bond-containing organic silicone resin at 50-90° C. for 30-120 min to obtain a pre-reactant; and
adding the hydrocarbon resin to the pre-reactant, and carrying out a reaction at 90-130° C. for 30-150 min to obtain the modified bismaleimide prepolymer.

4. The modified bismaleimide prepolymer according to claim 3, wherein 0.1-10 parts by weight of at least one of aminophenol, carboxylic acid or carboxylic anhydride is added during the reaction process of the bismaleimide compound, the double bond-containing organic silicone resin and the hydrocarbon resin.

5. The modified bismaleimide prepolymer according to claim 3, wherein the obtained modified bismaleimide prepolymer contains reactive double bonds.

6. A resin composition, comprising the following ingredients in parts by weight:
(a) modified bismaleimide prepolymer: 10-80 parts; and
(b) maleimide compound or derivatives thereof: 10-80 parts;
wherein the modified bismaleimide prepolymer is the modified bismaleimide prepolymer according to claim 1.

7. The resin composition according to claim 6, further comprising 3-50 parts by weight of elastomer, the elastomer being at least one of a styrene elastomer, a methacrylate elastomer and an organic silicone elastomer.

8. The resin composition according to claim 6, wherein the resin composition further comprises 5-50 parts by weight of flame retardant.

9. The resin composition according to claim 8, wherein the flame retardant is selected from a bromine flame retardant, a phosphorus flame retardant, a nitrogen flame retardant, an organic silicone flame retardant and an organic metal salt flame retardant;
the bromine flame retardant is selected from decabromodiphenyl ether, decabromodiphenyl ethane, brominated styrene or tetrabromophthalamide;
the phosphorus flame retardant is selected from inorganic phosphorus, phosphate ester, phosphoric acid, hypophosphorous acid, phosphorus oxide, 9,10-dihydro-9-oxa-10-phosphaphenanthrene-10-oxide (DOPO), 10-(2,5-dihydroxyphenyl)-9,10-dihydro-9-oxa-10-phosphaphenanthrene-10-oxide (DOPO-HQ), 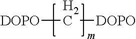
(m is an integer of 1 to 5), 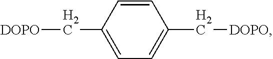
10-phenyl-9,10-dihydro-9-oxa-10-phosphaphenanthrene-10-oxide, tris(2,6-dimethylphenyl)phosphine, phosphazene and modified phosphazene;
the nitrogen flame retardant is selected from a triazine compound, a cyanuric acid compound, an isocyanic acid compound and phenothiazine;
the organic silicone flame retardant is selected from organic silicone oil, organic silicone rubber and organic silicone resin; and
the organic metal flame retardant is selected from ferrocene, an acetylacetone metal complex and an organic metal carbonyl compound.

10. The resin composition according to claim 6, further comprising a silane coupling agent and a dispersant, a weight ratio of the silane coupling agent to the dispersant being (2-10): 1.

11. The resin composition according to claim 10, wherein the silane coupling agent is an epoxy silane coupling agent, and the dispersant is a phosphate ester dispersant and/or a modified polyurethane dispersant.

12. Use of the resin composition according to claim 6 in a semi-cured sheet, a laminate, an insulating film, an insulating board, a copper clad laminate, a circuit substrate and an electronic device.
